(19) United States
(12) Patent Application Publication
(10) Pub. No.: US 2016/0324010 A1
(43) Pub. Date: Nov. 3, 2016

(54) METHOD FOR FORMING AN ELECTRICALLY CONDUCTING STRUCTURE ON A SYNTHETIC MATERIAL SUBSTRATE

(71) Applicant: FRAUNHOFER-GESELLSCHAFT ZUR FÖRDERUNG DER ANGEWANDTEN FORSCHUNG E.V., München (DE)

(72) Inventors: Matthias Fahland, Dresden (DE); Benjamin Graffel, Zwickau (DE); Gösta Mattausch, Ullersdorf (DE); Falk Winckler, Rippien (DE); Stefan Weiss, Dresden (DE); Sindy Mosch, Dresden (DE); Robert Jurk, Dresden (DE)

(73) Assignee: Fraunhofer-Gesellschaft zur Forderung der angewandten Forschung e.V., Munich (DE)

(21) Appl. No.: 15/100,464

(22) PCT Filed: Nov. 12, 2014
(86) PCT No.: PCT/EP2014/074373

§ 371 Date: May 31, 2016

(30) Foreign Application Priority Data
Dec. 4, 2013 (DE) 10 2013 113 485.8

(51) Int. Cl. H05K 3/12; C09D 11/52; C09D 11/037; H05K 1/09

(52) U.S. Cl. CPC H05K 3/1283; H05K 1/097; C09D 11/52; C09D 11/037; H05K 2203/092; H05K 2203/163; H05K 2203/085

(57) ABSTRACT

A method for forming an electrically conductive structure on a plastic substrate is provided. An ink, which contains electrically conductive solid particles, is printed on the plastic substrate, where copper particles are used as electrically conductive solid particles. After the printing of the ink, only the surface regions of the plastic substrate on which the electrically conductive structure is to be formed are swept over within a vacuum chamber by means of an electron beam having a first energy per unit length, causing sintering of the copper particles.

### CROSS-REFERENCE TO RELATED APPLICATIONS

This application is a 371 nationalization of PCT/EP2014/074373, entitled “VERFAHREN ZUM AUSBILDEN EINER ELEKTRISCH LEITFÄHIGEN STRUKTUR AUF EINEM KUNSTSTOFFSUBSTRAT,” having an international filing date of Nov. 12, 2014, the entire contents of which are hereby incorporated by reference, which in turn claims priority under 35 USC §119 to Germany patent application DE 10 2013 113 485.8 filed on Dec. 4, 2013, entitled “Verfahren zum Ausbilden einer elektrisch leitfähigen Struktur auf einem Kunststoffsubstrat,” the entire contents of which are hereby incorporated by reference.

### TECHNICAL FIELD

The invention relates to a method for forming an electrically conducting structure on a synthetic material substrate, wherein first an ink is printed onto a synthetic material substrate.

### BACKGROUND

Lithographic and galvanic methods are widely used for the production of strip conductors on circuit boards and also in microelectronic and sensory components. These methods, however, are very complex and expensive, and are thus ill-suited for small quantity production and for rapid prototyping. Some very flexible alternative techniques, for example, are direct printing methods, such as aerosol and inkjet printing. But the disadvantage here is that chiefly high-cost, nano-scale silver inks have to be used for this method. Here, the metal particles are coated with an organic film which prevents agglomeration and sedimentation in the ink. In order to reduce the electrical resistance of the circuit path structures printed with such inks, the organic constituents have to be removed from the circuit path structures.

From US 2010/0178434 A1 a method is known in which a silver-containing ink is printed onto a substrate. In addition to a silver-containing compound, the ink also contains a dispersion stabilizer and a solvent. After the circuit has been printed, the entire substrate is heated by an electron beam to over 190° C. in order to remove the organic material remaining on the substrate and thus form circuit paths of silver. Due to the heating of the substrate to above 190° C., use of the method is restricted in terms of the substrate materials that can be employed, in particular with respect to synthetic material substrates. An additional disadvantage is the high cost of silver-containing ink needed for the method.

DE 699 21 515 T2 discloses a method for providing circuit paths on a printed circuit in which first the structure of the circuit is printed onto a substrate using an electrically conducting and hardening ink. The printed circuit paths are then reinforced by electroplating with a copper sulfate solution and then subjected to an electron beam in order to ionize the circuit paths and change their electrical polarity. The disadvantage here is that this is a multiple-step process which requires wet chemistry.

In US 2005/0255253 A1, on the other hand, it is proposed that the surface of a substrate onto which an electrically conducting, polymer-containing ink has been printed be cured with an electron beam. With this method, however, the electron beam is not used to remove organic material from the substrate, but rather to harden the ink due to radiation-induced polymer crosslinking. A disadvantage of this method is that the electrical conductance of circuit paths that have polymer constituents is not particularly good.

### BRIEF DESCRIPTION OF THE DRAWINGS

FIG. 1 is a schematic depiction of a synthetic material substrate on which an electrically conducting structure is to be formed.

### DETAILED DESCRIPTION

The invention is therefore based on the technical problem of creating a method by means of which the disadvantages of the prior art can be overcome. In particular, using the inventive method, it should be possible to form an electrically conducting structure on synthetic material substrates as well; it should be possible to use a low-cost ink; and the method should result in high electrical conductance of the circuit path structure formed on the substrate.

With the inventive method of forming an electrically conducting structure on a synthetic material substrate, an ink containing electrically conducting solid particles is first printed onto the synthetic material substrate, at least on those surface regions where the electrically conducting structure is to be formed. According to the invention, copper particles are used as electrically conducting solid particles. One advantage here is that inks containing copper particles are lower in cost than inks whose electrically conducting particles consist of precious metals. Because the oxidation of copper particles usually cannot be prevented under atmospheric storage conditions, the term copper particles, in the inventive sense, is also understood as including copper particles which have a partial or complete oxide coating on their surface. But it is also expressly stated that an oxidation of the copper particles is neither necessary nor desirable for the inventive method. Therefore, according to the invention, the term “copper particles” also includes oxides and alloys which have a copper fraction of at least 90%.

However, printing with inks containing copper particles alone does not produce a useful electrically conducting structure on a substrate, in particular because oxidation on the surface of the copper particles, which cannot usually be completely prevented, prevents a good electrical contact from being established between adjoining copper particles. This is a disadvantage compared to inks containing precious metals, whose particles do not tend to oxidize as quickly as copper. The ink containing copper particles that is applied during printing thus requires additional processing. According to the invention, after printing using the ink containing copper particles, only the surface regions of the synthetic material substrate on which the electrically conducting structure is to be formed are cured in a vacuum chamber with electron beam at a first energy per unit length. Here, an energy per unit length is chosen such that an energy applied to the printed ink during curing of the ink with the electron beam will cause a sintering of the copper particles. This sintering of the copper particles causes the mutually adjoining copper particles to melt together only at points or in smaller surface regions, so that a good electrically conducting contact from one copper particle to neighboring copper particles is created, and thus an electrically conducting structure is formed. Due to the curing of the ink containing copper particles, any organic constituents in the ink are also simultaneously removed from the synthetic material substrate.

Because only surface regions of a substrate on which an electrically conducting structure is to be formed are cured using the electron beam with the first energy per unit length, and because here the energy is introduced primarily into the copper particles of the ink, the inventive method is also suitable for temperature-sensitive substrates, such as synthetic material substrates. However conductive structures can also be formed using the inventive method on other substrate materials, such as semiconductors, glass or ceramics, for example.

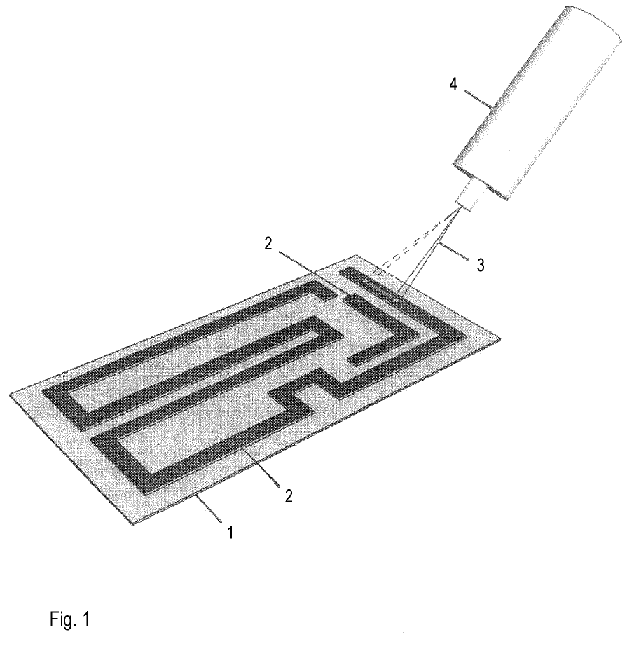

The present invention will be explained in greater detail below based on exemplary embodiments. FIG. 1 is a schematic depiction of a synthetic material substrate 1 on which an electrically conducting structure is to be formed. According to the invention, an ink is first printed onto the synthetic material substrate 1; this ink contains electrically conducting particles in the form of copper particles. The ink is printed at least in the surface regions of the synthetic material substrate 1 where an electrically conducting structure 2 is to be created. In the exemplary embodiment associated with FIG. 1, only those surface regions of the synthetic material substrate 1 are printed with the ink on which the electrically conducting structure 2 is to be created. All ink printing processes known from the prior art, such as ink jet, aerosol jet, spray or screen printing, for example, can be used for the printing process step.

An ink used according to the invention is characterized in that the percentage of copper particles in the ink amounts to at least 15 wt % and the copper particles have a size in the range 5 nm to 100 μm. Preferably, copper particles with a size in the range of 5 nm to 1 μm are used, because particles in this size range can form particularly delicate and filigree circuit path structures. In addition to copper particles, the ink can also contain solvent, water, and additives to regulate the ink viscosity, as is known from other inks used for printing circuits. In one exemplary embodiment, a copper-containing ink is used, which is composed of a low viscosity suspension with a viscosity of less than 5 Pa·s (Pascal-seconds).

After the ink has been printed, the copper particles in the printed ink are sintered on the surface regions of the synthetic material substrate 1 on which the electrically conducting structure 2 is to be formed, and thus an electrically conducting contact is established between mutually adjoining copper particles within these surface regions. In order to do so, the synthetic material substrate 1 is placed in a vacuum chamber (not depicted in FIG. 1).

Inside the vacuum chamber, only those surface regions of the synthetic material substrate 1 on which the electrically conducting structure 2 is to be formed, are cured with an electron beam 3 with a first energy per unit length, and this causes a sintering of the copper particles.

An electron beam is particularly suitable for introducing the energy required for sintering into the copper particles, because this kind of electron beam can be generated as having a very small beam focus, and thus very delicate circuit path structures can be formed. Furthermore, an electron beam can be deflected very quickly with high precision, which results in a high productivity with high precision. Another advantage is that with an electron beam, the depth distribution of the introduced energy is adjustable, so that the energy needed for sintering the copper particles is also introduced predominately into the copper particles, and the underlying substrate can thus be placed under less thermal stress. The inventive method is thus particularly suitable for synthetic material substrates.

It should be noted in particular at this point that according to the invention, only a sintering of the copper particles is effected by the energy of the electron beam 3, along with simultaneous burn-off of organic constituents, and not a complete melting of the copper particles. The energy per unit length required to do so, and to cure the printed ink in order to effect a sintering of the copper particles, can be easily determined for each application by means of laboratory tests, depending on the kind of substrate and the composition of the copper-containing ink. The energy per unit length for curing a substrate with an electron beam is determined by dividing the electric power of the electron beam by the rate of advance of the electron beam. Suitable for the inventive method is an electron beam 3 generated by an electron beam generator 4 having a power output of 1 W to 150 W, wherein a rate of advance of the electron beam 3 can be used at which the electron beam 3 scans the synthetic material substrate 1 at a speed of 0.1 m/s to 100 m/s.

Two possible procedures can be used for curing the synthetic material substrate 1 with the electron beam 3 at the first energy per unit length in order to form the electrically conducting structure 2. Firstly, the synthetic material substrate 1 can be placed in the vacuum chamber and then checked to determine whether the synthetic material substrate 1 is properly aligned in the vacuum chamber. If the check shows that the synthetic material substrate is properly aligned, the surface of the synthetic material substrate 1 can then be scanned according to a defined geographic pattern of the electrically conducting structure that is to be formed by means of the electron beam 3.

In an alternative embodiment, during the curing of the synthetic material substrate 1 with the electron beam 3, back-scatter electrons and/or secondary electrons can be measured by means of a sensor unit (not depicted in FIG. 1) and from this, by using an evaluation unit (likewise not depicted in the FIGURE), a signal is created which is used to control the direction of the electron beam 3. With this procedure it can be checked and assured that the position of the electron beam 3 on the surface of the synthetic material substrate rests within the surface regions where the electrically conducting structure is to be formed. The sensor units required for detecting secondary and back-scatter electrons with the associated evaluation and control devices are already known, for example from electron beam welding, and can be easily integrated into apparatus and methods for forming a conducting structure.

In order to check the position of the electron beam 3 on the surface of the synthetic material substrate 1, or check whether the synthetic material substrate 1 is also properly aligned inside the vacuum chamber, in an additional embodiment of the method according to the invention, the synthetic material substrate is cured by means of an electron beam 3 with a second energy per unit length, wherein the second energy per unit length is selected to be less than the first energy per unit length. The curing of the synthetic material substrate 1 by means of the electron beam 3 with the second energy per unit length thus firstly does not result in a sintering of copper particles, and secondly does not result in thermally induced damage to the synthetic material substrate 1. When the synthetic material substrate 1 is cured with the second energy per unit length, both surface regions of the synthetic material substrate 1 can be cured on which an electrically conducting structure 2 is to be formed, and also surface regions on which no electrically conducting structure 2 is to be formed. Here too, secondary and/or back-scatter electrons are measured by means of the sensor unit. Then, by using the resultant contrast image of the surface of the synthetic material substrate 1, it can be determined whether the synthetic material substrate 1 is properly aligned within the vacuum chamber and/or whether the electron beam 3, when it is operating at the first energy per unit length upon the surface of the synthetic material substrate 1, is still operating within the surface regions where the electrically conducting structure 2 is to be formed. Thus the electron beam 3 can be switched, at intermittent intervals, while curing the surface of the synthetic material substrate with the first energy per unit length to the second energy per unit length and scan the entire surface of the synthetic material substrate 1 at the second energy per unit length in order to check its position on the surface of the synthetic material substrate 1 and subsequently continue the curing of the synthetic material substrate 1 with the first energy per unit length. The control apparatus required for switching the energy per unit length of an electron beam and for controlling the direction of the electron beam are known.

In the exemplary embodiment described in FIG. 1, the synthetic material substrate 1 was only printed with the ink containing copper particles in those surface regions where the electrically conducting structure 2 is to be formed. However alternatively, it is also possible to print the entire surface of the synthetic material substrate 1, in addition to the regions of the electrically conducting structure, with an ink which contains copper particles. Thus, for example, the entire surface of the synthetic material substrate 1 can be printed with the copper-containing ink or it can be coated with copper particles. Subsequently, only the surface regions of the synthetic material substrate 1 where the electrically conducting structure 2 is to be formed can be cured again, using the first energy per unit length, with the electron beam 3. Then after the electrically conducting structure 2 has been formed, the ink is removed from the other surface regions of the synthetic material substrate 1 where the copper particles were not sintered by means of the electron beam. This can take place, for example, in that the ink that was not subjected to the electron beam 3 operating at the first energy per unit length is removed from the surface of the synthetic material substrate 1 by mechanical or chemical means.

The electrical conductance of an electrically conducting structure 2 produced according to the invention can be additionally increased in that a gas that reduces the oxidation of the copper particles is introduced into the vacuum chamber while the ink containing copper particles is being scanned by an electron beam 3. Hydrogen has proven to be a particularly suitable gas for this purpose, because it removes oxygen from an oxidized edge layer of copper particles and binds with them to form water, which evaporates from the ink. An oxidized edge layer of copper particles is reduced in this manner, and the electrical conductance of the electrically conducting structure 2 formed is thereby increased. Alternatively, a gas containing hydrogen can also be used for this purpose.

In the description of the preceding exemplary embodiments, the surface of the synthetic material substrate is cured by means of an electron beam at only one position. However with the inventive method, known apparatus with multiple beam techniques can also be used, wherein one electron beam is quickly deflected such that it cures the surface of the synthetic material substrate more or less simultaneously at a plurality of locations, as is known for example, from electron beam welding. In this way, using the inventive method, the sintering of the circuit path structures can be carried out at a plurality of locations simultaneously. With embodiments of this kind employing multiple beam technique, it is also possible to use electron beam generators with a power output of up to 10 kW and with a rate of deflection of up to 11.4 km/s.

1. A method for forming an electrically conducting structure on a synthetic material substrate, the method comprising:
printing an ink which contains electrically conducting solid particles onto a synthetic material substrate, wherein copper particles are used as the electrically conducting solid particles, and
curing inside a vacuum chamber by means of an electron beam with a first energy per unit length, after the ink has been printed, only the surface regions of the synthetic material substrate on which the electrically conducting structure is to be formed, the curing causing sintering of the copper particles.

2. The method according to claim 1, further comprising measuring back-scattering and/or secondary electrons by means of a sensor unit, from which a signal is formed, which is used to control the direction of the electron beam.

3. The method according to claim 2, wherein to determine the position of the electron beam, the synthetic material substrate is intermittently swept over using the electron beam with a second energy per unit length, wherein the second energy per unit length has a lesser intensity than the first energy per unit length.

4. The method according to claim 1, wherein an electron beam with a beam power of 1 W to 150 W is used.

5. The method according to claim 1, wherein an electron beam with a deflection speed of 0.1 m/s to 100 m/s passes over the synthetic material substrate.

6. The method according to claim 1, wherein an ink with a content of copper particles of at least 15 wt % is used.

7. The method according to claim 1, wherein copper particles with a particle size of 5 nm to 100 μm are used.

8. The method according to claim 7, wherein copper particles with a particle size of 5 nm to 1 μm are used.

9. The method according to claim 1, wherein the entire surface of the synthetic material substrate is printed with ink containing copper particles.

10. The method according to claim 1, wherein only the surface regions of the synthetic material substrate on which the electrically conducting structure is to be formed, are printed with the ink containing copper particles.

11. The method according to claim 1, wherein during the curing of the synthetic material substrate with the electron beam, a gas is introduced into the vacuum chamber which reduces the oxidation of the copper particles.

12. The method according to claim 11, wherein hydrogen is introduced into the vacuum chamber.

13. The method according to claim 1, wherein an ink with a viscosity of less than 5 Pa·s is used.
